(19) United States
(12) Patent Application Publication
(10) Pub. No.: US 2016/0351548 A1
(43) Pub. Date: Dec. 1, 2016

(54) LIGHT EMITTING DIODE DISPLAY DEVICE AND MANUFACTURING METHOD THEREOF

(71) Applicant: MIKRO MESA TECHNOLOGY CO., LTD., APIA (WS)

(72) Inventors: Li-Yi CHEN, Tainan City (TW); Chih-Hui CHAN, Tainan City (TW); Chun-Yi CHANG, Tainan City (TW); Pei-Yu CHANG, Tainan City (TW)

(21) Appl. No.: 14/723,475

(22) Filed: May 28, 2015

(51) Int. Cl. H01L 25/075; H01L 33/62; H01L 33/44; H01L 21/66

(52) U.S. Cl. CPC H01L 25/0753; H01L 22/20; H01L 33/62; H01L 33/44; H01L 2933/0066; H01L 2933/0033; H01L 2933/0025

(57) ABSTRACT

A manufacturing method of a light emitting diode (LED) display device includes forming at least one sub-pixel circuit on a substrate, forming a primary electrical pad and a first backup electrical pad electrically connected to the sub-pixel circuit, disposing a first micro light emitting device on the primary electrical pad and testing the first micro light emitting device.

### BACKGROUND

Technical Field

The present disclosure relates to a light-emitting diode display device.

Description of Related Art

In recent years, advances in LED technology have made dramatic improvement in luminance intensity and color fidelity. Due to theses improved technology, a full color LED display device has become available and in common use.

The full color LED display device can be performed by attaching different colors of micro light emitting devices onto a display substrate. These different colors of micro light emitting devices emit different light colors, and thus a color image can be displayed according to the combination of different colored light. However, when a micro light emitting device is found to be defective, it is hard to replace the defective micro light emitting device because the detaching process is hard to perform and may cause damage to the display substrate or other micro light emitting devices.

### SUMMARY

According to one embodiment of the present invention, a manufacturing method of a light emitting diode (LED) display device is provided. The method includes forming at least one sub-pixel circuit on a substrate, forming a primary electrical pad and a first backup electrical pad electrically connected to the sub-pixel circuit, disposing a first micro light emitting device on the primary electrical pad and testing the first micro light emitting device.

According to another embodiment of the present invention, a manufacturing method of an LED display device is provided. The method includes forming an array of sub-pixels on a substrate, in which the formation of each of the sub-pixel includes forming at least one sub-pixel circuit on the substrate, forming a primary electrical pad and a first backup electrical pad electrically connected to the sub-pixel circuit, and disposing a first micro light emitting device on the primary electrical pad. Thereafter, the manufacturing method of the LED display device includes testing the first micro light emitting device of each of the sub-pixels and collecting test result and position information of the first micro light emitting device of each of the sub-pixels.

According to yet another embodiment of the present invention, an LED display device is provided. The LED display device includes a substrate, at least one sub-pixel circuit, a plurality of electrical pads and a micro light emitting device. The substrate includes at least one sub-pixel. The sub-pixel circuit is disposed on the substrate. The electrical pads are disposed inside the sub-pixel and are electrically connected with the sub-pixel circuit. The micro light emitting device is disposed on one of the electrical pads.

Since each of the sub-pixel includes a plurality of electrical pads, when a micro light emitting device is tested to be defective, it is only needs to attach another micro light emitting device onto another electrical pad. As a result, there is no need to perform detaching process which may cause damage to the substrate or to other micro light emitting devices. Therefore, the yield rate of manufacturing the LED display device is increased.

It is to be understood that both the foregoing general description and the following detailed description are by examples, and are intended to provide further explanation of the invention as claimed.

### BRIEF DESCRIPTION OF THE DRAWINGS

FIG. 1 is a flow chart of manufacturing method of a light emitting diode (LED) display device in accordance with an embodiment of the present invention.

FIG. 2 is a top view of an LED display device in accordance with an embodiment of the present invention.

FIG. 3A is a top view of the sub-pixel illustrating manufacturing steps S1 and S2 in FIG. 1.

FIG. 3B is a cross-sectional view of FIG. 3A taken along line 3.

FIG. 3C is a top view of the sub-pixel with different shapes of electrical pads.

FIG. 4A is a top view of the sub-pixel illustrating manufacturing step S3 in FIG. 1.

FIG. 4B is a cross-sectional view of FIG. 4A taken along line 4.

FIG. 5 illustrates a test device for testing the micro light emitting device in accordance with an embodiment of the present invention.

FIG. 6 is a cross-sectional view of the sub-pixel illustrating manufacturing steps S5˜S7 in FIG. 1.

FIG. 7A is a top view of the sub-pixel illustrating manufacturing steps S8 and S9 in FIG. 1 after testing of a defective first micro light emitting device.

FIG. 7B is a cross-sectional view of FIG. 7A taken along line 7 in accordance with an embodiment of the present invention.

FIG. 7C is a cross-sectional view of FIG. 7A taken along line 7 in accordance with another embodiment of the present invention.

FIG. 8A is a top view of the sub-pixel illustrating manufacturing steps S8 and S9 in FIG. 1 after testing of defective second micro light emitting device.

FIG. 8B is a cross-sectional view of FIG. 8A taken along line 8.

FIG. 9 is an enlarged cross-sectional of the sub-pixel with multiple openings and opposite electrodes on the micro light emitting device in accordance with an embodiment of the present invention.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

The terms “micro” device or “micro” LED as used herein may refer to the descriptive size of certain devices in accordance with embodiments of the present invention. As used herein, the terms “micro” device or “micro” LED are meant to refer to the scale of 1 micrometer to 1 millimeter. However, it is to be appreciated that embodiments of the present invention are not necessarily so limited, and that certain aspects of the embodiments may be applicable to larger, and possibly smaller size scales.

It will be understood that when an element is referred to as being “on” another element, it can be directly on the other element or intervening elements may be present there between. In contrast, when an element is referred to as being “directly on” another element, there are no intervening elements present.

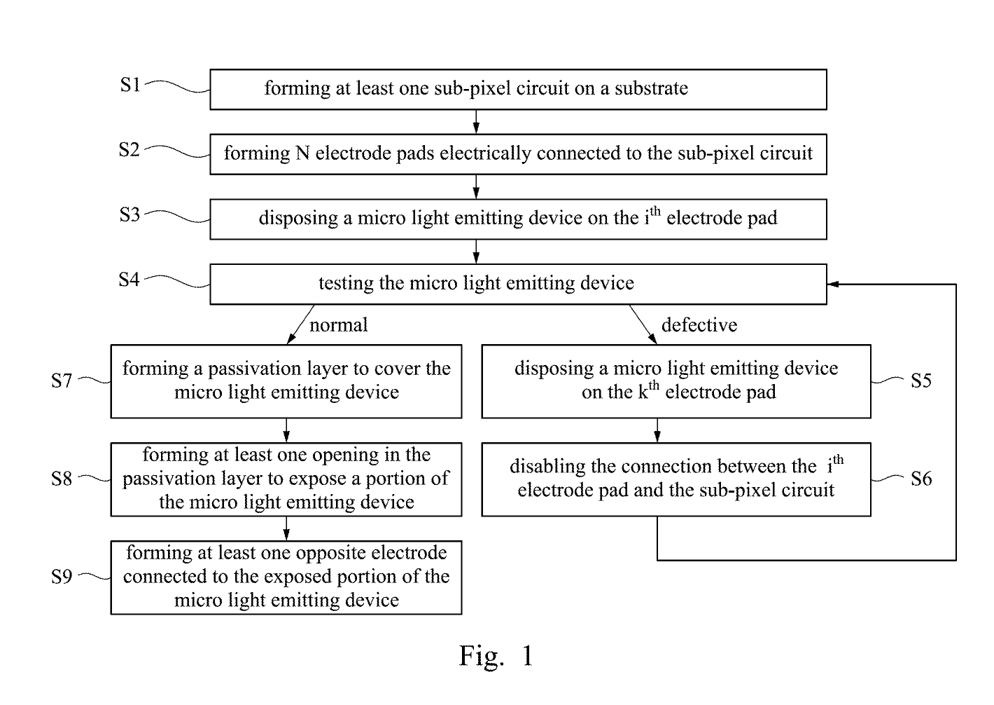

FIG. 1 is a flow chart of manufacturing method of a light emitting diode (LED) display device in accordance with an embodiment of the present invention. As shown in FIG. 1, the manufacturing method includes following steps:

Step S1: forming at least one sub-pixel circuit on a substrate;

Step S2: forming N electrode pads electrically connected to the sub-pixel circuit, wherein N is a natural number and N≧2;

Step S3: disposing a micro light emitting device on the i^{th} electrode pad, wherein i is a natural number and i≦N;

Step S4: testing the micro light emitting device;

Step S5: disposing a micro light emitting device on the k^{th} electrode pad, wherein k is a natural number, k≦N and k≠i; and

Step S6: disabling the connection between the i^{th} electrode pad and the sub-pixel circuit.

Step S7: forming a passivation layer to cover the micro light emitting device;

Step S8: forming at least one opening in the passivation layer to expose a portion of the micro light emitting device;

Step S9: forming at least one opposite electrode connected to the exposed portion of the micro light emitting device.

Through the aforementioned manufacturing steps S1˜S9, when a micro light emitting device is tested to be defective, there is no necessary to detach the defective micro light emitting device from the electrode pad. Because there are multiple electrode pads within the sub-pixel, it only needs to attach another micro light emitting device to another electrode pad. As a result, the damage caused by the detaching process can be avoided, and the yield rate of manufacturing the LED display device is improved.

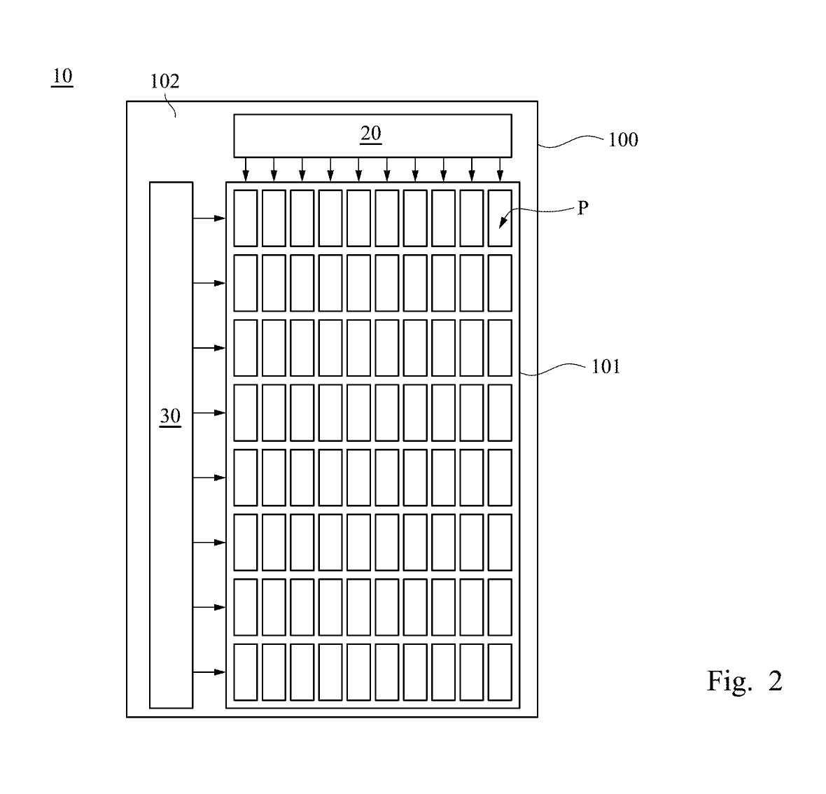

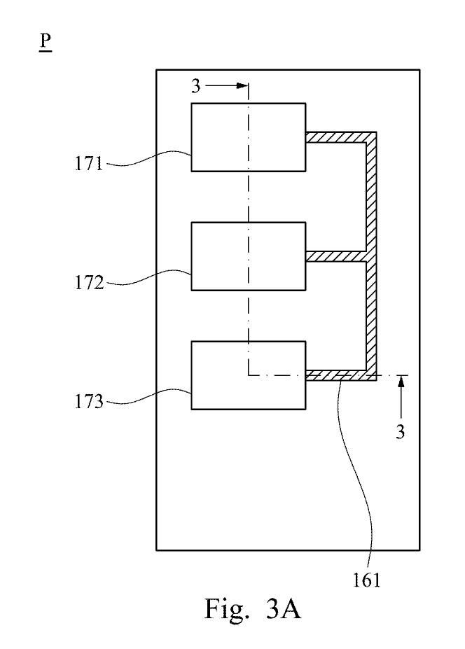

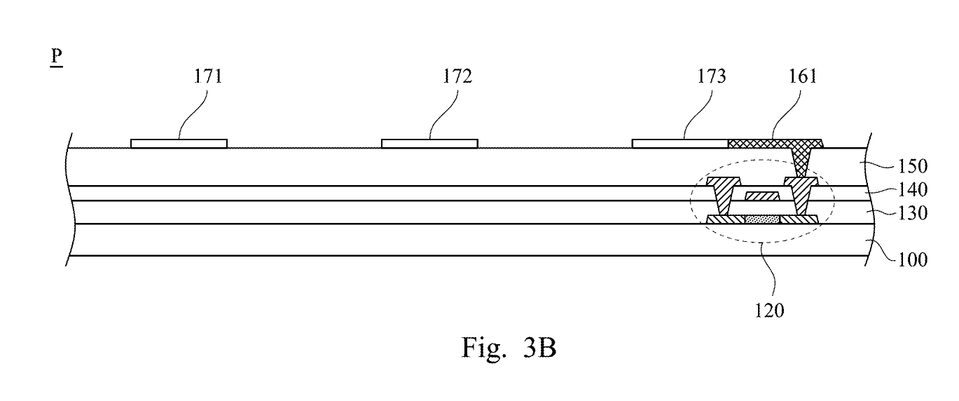

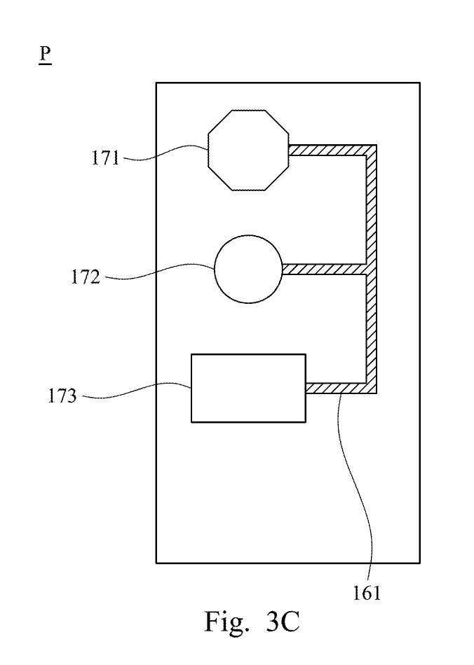

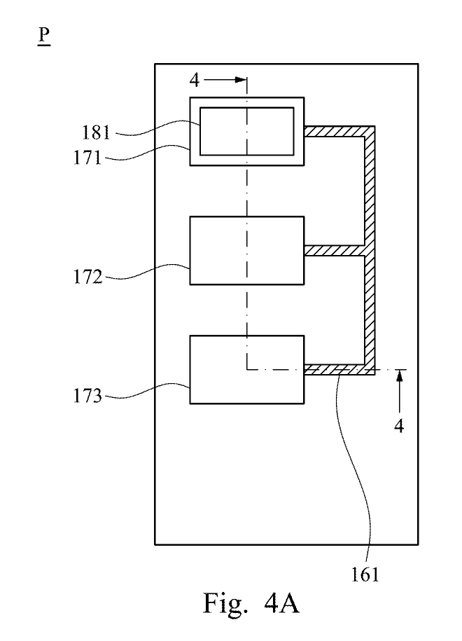

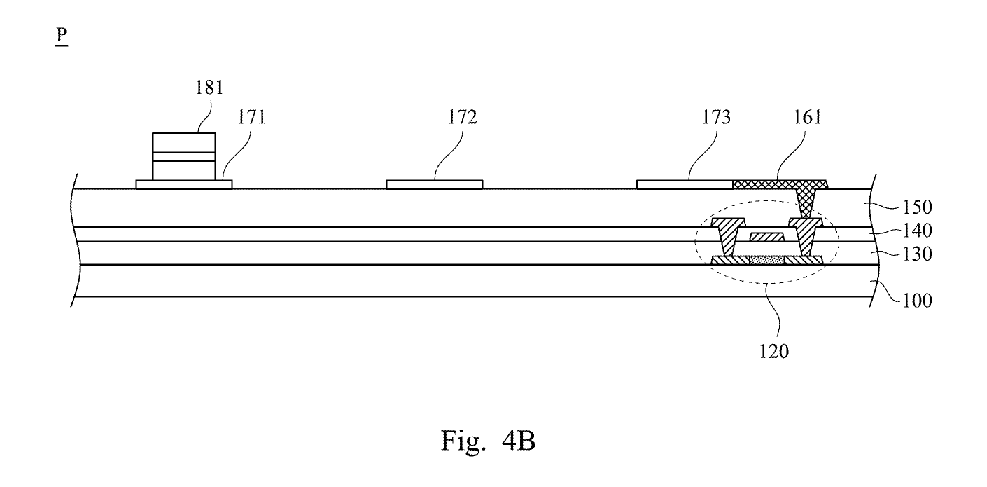

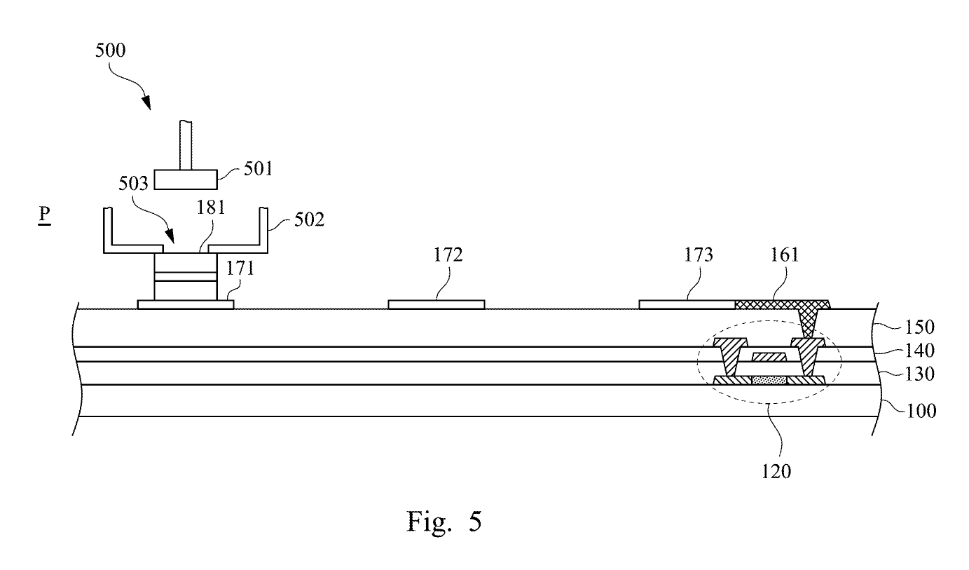

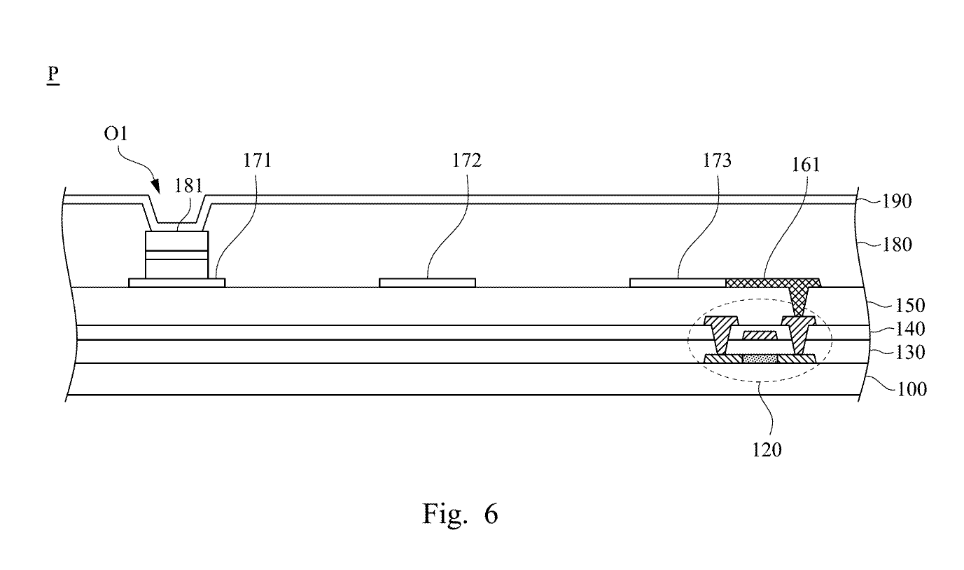

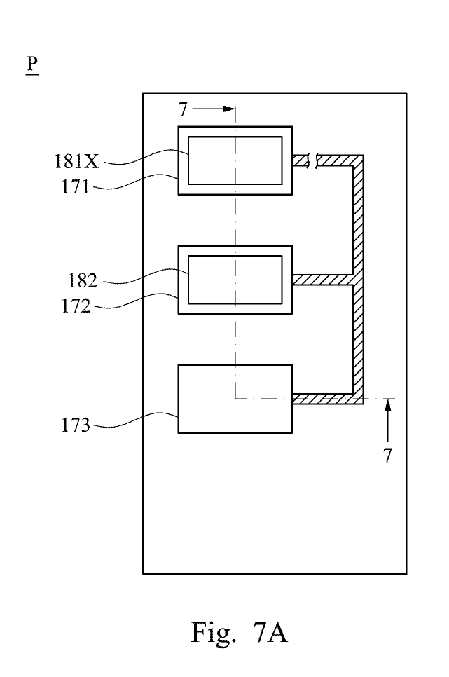

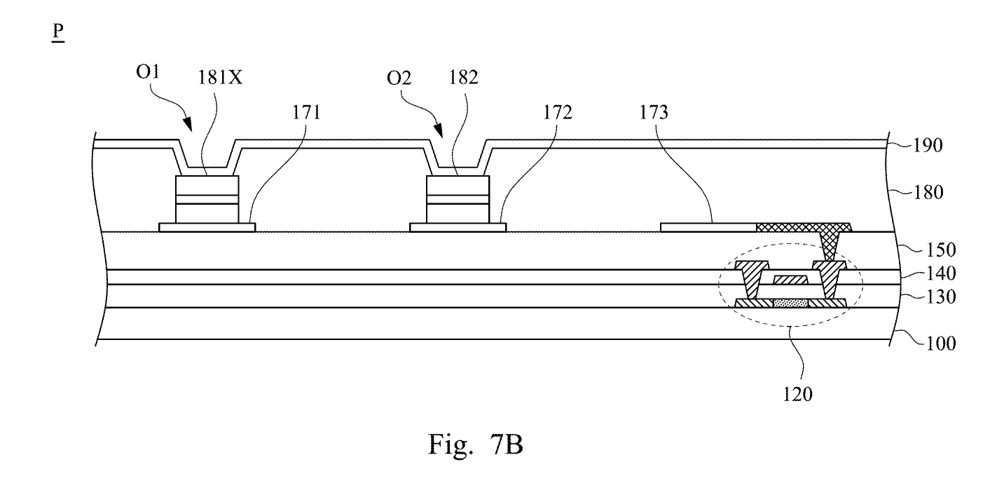

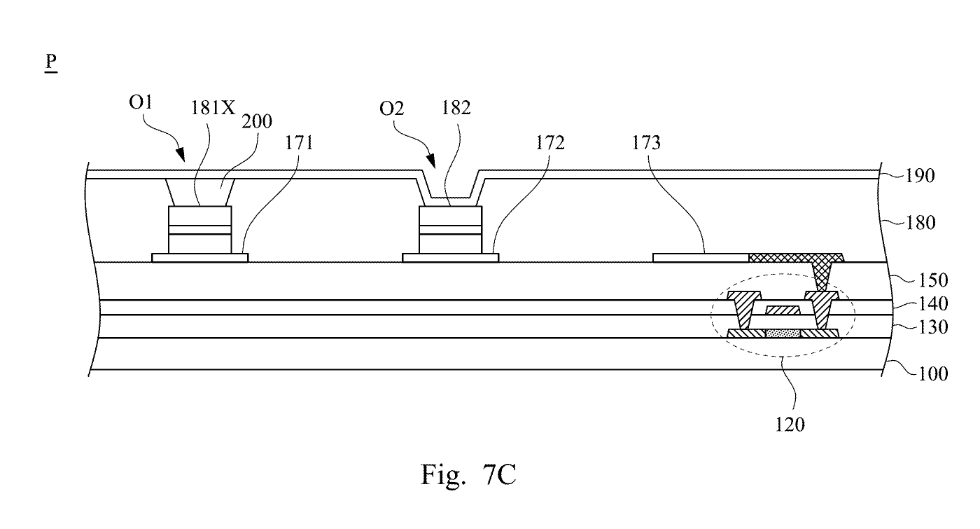

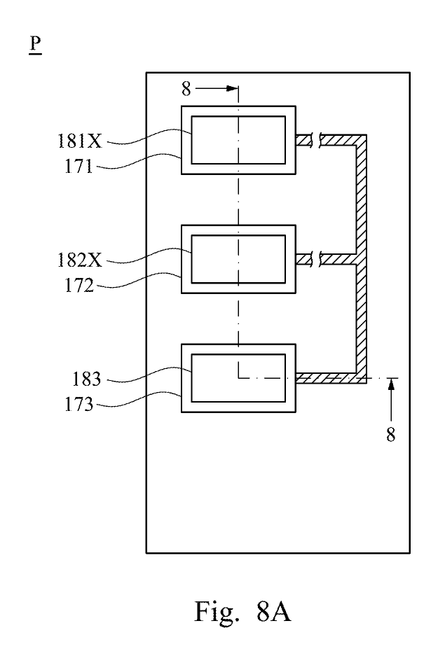

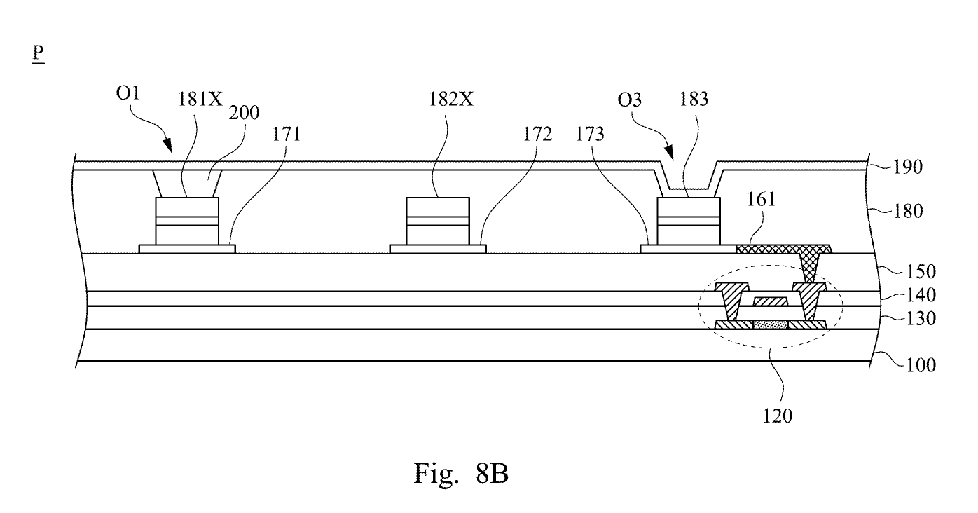

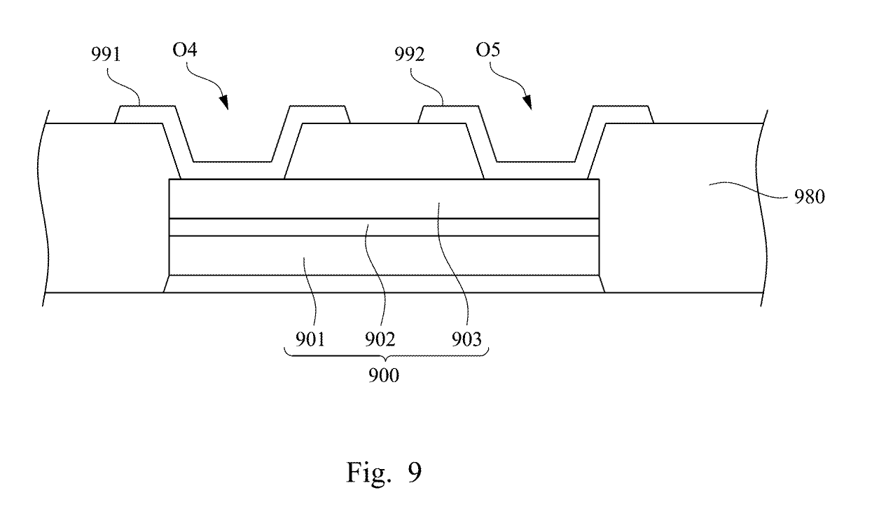

The following description illustrates how to perform the aforementioned steps S1-S9 with reference made to FIGS. 2-8. FIG. 2, FIGS. 3A, 3B and 3C illustrate the manufacturing steps S1, S2 of an LED display device. FIGS. 4A and 4B illustrate the manufacturing step S3 of an LED display device. FIG. 5 illustrates the manufacturing step S4 of an LED display device. FIG. 6 illustrates the manufacturing steps S7˜S9. FIGS. 7A, 7B, 7C, 8A and 8B illustrate the manufacturing steps S5˜S9. FIG. 9 illustrates the manufacturing steps S7˜S9 with multiple openings and opposite electrodes.

FIG. 2 is a top view of an LED device in accordance with an embodiment of the present invention. In step S1, at least one sub-pixel circuit is formed on a substrate. As shown in FIG. 2, the LED display device 10 includes an array of sub-pixels P formed on the substrate 100. More specifically, the substrate 100 may support a pixel area 101 and a non-pixel area 102. The pixel area 101 includes the array of sub-pixels P arranged in a matrix. The non-pixel area 102 includes a data driver circuit 20 and a scan driver circuit 30. The data driver circuit 20 and the scan driver circuit 30 are electrically connected to each sub-pixel P.

FIG. 3A is a top view of the sub-pixel P illustrating manufacturing steps S1 and S2. FIG. 3B is a cross-sectional view of FIG. 3A taken along line 3. As shown in FIG. 3A and FIG. 3B, the formation of each of the sub-pixels P includes forming a sub-pixel circuit 120 on the substrate 100. More specifically, the formation of each of the sub-pixel P includes forming interlayer insulating layers 130, 140, and the sub-pixel circuit 120 is formed in the interlayer insulating layers 130, 140. In the embodiment of FIG. 3B, the sub-pixel circuit 120 is directly formed on the substrate 100, but the present invention is not limited thereto. In some embodiments, the sub-pixel circuit 120 may be indirectly formed on the substrate 100. That is, there may be another layer disposed between the sub-pixel circuit 120 and the substrate 100.

In step S2, N electrode pads are formed and are electrically connected to the sub-pixel circuit 120. With reference made to FIG. 3A and FIG. 3B, after forming the sub-pixel circuit 120, a planarization layer 150 is formed to cover the sub-pixel circuit 120. A control line 161 is formed on the planarization layer 150 and is electrically connected to the sub-pixel circuit 120. As shown in FIGS. 3A, 3B and 3C, 3 electrode pads including a primary electrical pad 171, a first backup electrical pad 172 and a second backup electrical pad 173 are formed on the planarization layer 150, and the primary electrical pad 171, the first backup electrical pad 172 and the second backup electrical pad 173 are electrically connected to the sub-pixel circuit 120 through the control line 161. In various embodiments, the primary electrical pad 171, the first backup electrical pad 172 and the second backup electrical pad 173 can be acted as a pixel electrode. It should be understood that, the number of the electrical pads of the present invention are not limited to 3. In other embodiments, the number of the electrical pads may be 2 including the primary electrical pad 171 and the first backup electrical pad 172. In some embodiments, the number of the electrical pads may greater than 4 including the primary electrical pad 171, the first backup electrical pad 172, the second backup electrical pad 173, the third backup electrical pad (not illustrated) and so on.

In some embodiments, the planarization layer 150 is optional. In this case, the control line 161, the primary electrical pad 171, the first backup electrical pad 172 and the second backup electrical pad 173 are formed on the interlayer insulating layer 140, and the primary electrical pad 171, the first backup electrical pad 172 and the second backup electrical pad 173 are electrically connected with the sub-pixel circuit 120 through the control line 161.

As shown in FIG. 3A, the primarily electrode pad 171, the first backup electrical pad 172 and the second backup electrical pad 173 have substantially the same shape, e.g. a rectangular shape. However, the present invention is not limited thereto. FIG. 3C is a top view of the sub-pixel P illustrating manufacturing step S2 in accordance with another embodiment of the present invention. As shown in FIG. 3C, the primarily electrode pad 171, the first backup electrical pad 172 and the second backup electrical pad 173 have variety of shapes, e. g. an octagonal shape, a circular shape, and a rectangular shape. It should be understood that the shapes of the electrical pads can be different or be the same depending on the shapes of the micro light emitting device to be formed thereon. For example, in some embodiments, the shapes of the electrical pads inside the sub-pixel P can be selected from the group consisting of circle, triangle, square, pentangle, hexagon or other polygon.

FIG. 4A is a top view of the sub-pixel P illustrating manufacturing step S3 in accordance with an embodiment of the present invention. FIG. 4B is a cross-sectional view of FIG. 4A taken along line 4. In step S3, a micro light emitting device is disposed on the i^{th} electrode pad. As shown in FIG. 4A and FIG. 4B, a first micro light emitting device 181 is disposed on the primary electrical pad 171. In the present embodiment, the first micro light emitting device 181 can be a micro light emitting diode (LED), and the micro LED can be disposed on the primary electrical pad 171 through a transfer device (not illustrated). The transfer device may have a transfer head for gripping the micro LED from an LED carrier substrate. Then, the transfer device can transfer the micro LED onto the primary electrical pad 171 from the LED carrier substrate.

FIG. 5 illustrates a test device 500 for testing the micro light emitting device in accordance with an embodiment of the present invention. In step S4, the micro light emitting device is tested. As shown in FIG. 5, a test device 500 is provided. The test device 500 may include a photo sensor 501 and an electrode 502. The electrode 502 may have an opening part 503. As shown in FIG. 5, when testing the first micro light emitting device 181, the electrode 502 is electrically connected to the first micro light emitting device 181, and the opening part 503 can expose at least a portion of the first micro light emitting device 181. The photo sensor 501 can detect the emission of the first micro light emitting device 181 through the opening part 503, and an analyzer (not illustrated) can analyze the luminance of the first micro light emitting device 181. If the first micro light emitting device 181 exhibits no luminance or irregular luminance, the first micro light emitting device 181 may be defective. In some embodiments, the analyzer can further analyze the current flow of the electrode 502. For example, an I-V (current-voltage) curve or a leakage current can be obtained through the current flow of the electrode 502. If the first micro light emitting device 181 exhibits irregular I-V curve or abnormal leakage current, the first micro light emitting device 181 may be defective.

Referring to FIG. 2 and FIG. 5, the testing is performed on each of the sub-pixels P on the substrate 100. After the testing, a data acquisition module (not illustrated) can collect the test result and the position information of the first micro light emitting device 181 of each of the sub-pixels P. Thereafter, if most or all of the first micro light emitting device 181 is tested to be normal, the steps S7˜S9 are performed. In certain application, if 99.8% of the first micro light emitting devices 181 are tested to be normal, the steps S7˜S9 may be performed. On the other hand, if at least a predetermined percentage of the first micro light emitting device 181 is tested to be defective, the steps S5˜S6 are performed. In practical application, if at least 0.2% of the first micro light emitting device 181 is tested to be defective, the steps S5˜S6 may be performed. It should be understood that, the defect rate of performing S5-S6 could be set to meet the product specification.

FIG. 6 is a cross-sectional view of the sub-pixel P illustrating manufacturing steps S7˜S9 in accordance with an embodiment of the present invention. In step S7, a passivation layer is formed to cover the micro light emitting device. In step S8, at least one opening is formed in the passivation layer to expose a portion of the micro light emitting device. In step S9, at least one opposite electrode is formed to connect to the exposed portion of the micro light emitting device.

As shown in FIG. 6, the passivation layer 180 is formed around the first micro light emitting device 181 and the passivation layer 180 partially covers the first micro light emitting device 181. In the present embodiment, the passivation layer 180 also covers the control line 161 within the sub-pixel P. There is an opening O1 in the passivation layer 180 to expose a portion of the first micro light emitting device 181, and an opposite electrode 190 is electrically connected to the exposed portion of the first micro light emitting device 181. More specifically, after the passivation layer 180 covers the first light emitting device 181 and the control line 161, an exposing, a developing and/or an etching process can be performed to open the passivation layer 180, ensuring at least a portion of the top surface of the first micro light emitting device 181 is exposed, so as to enable the opposite electrode 190 to make an electrical contact with the first micro light emitting device 181.

FIG. 7A is a top view of the sub-pixel P illustrating manufacturing steps S5 and S6 after testing of a defective first micro light emitting device 181X. FIGS. 7B and 7C are a cross-sectional view of FIG. 7A taken along line 7. In step S5, a micro light emitting device is disposed on the k^{th} electrode pad. In step S6, the connection between the i^{th} electrode pad and the sub-pixel circuit is disabled. However, in some embodiments, the step S6 may be optional, if the defective micro LED is open circuit or merely has minor influence on the pixel electric characteristic.

As shown in FIG. 7A and FIG. 7B, the first micro light emitting device 181X is tested to be defective in step S4. In more detail, the detection test in step S4 may indicate that the first micro light emitting device 181X is defective if the first micro light emitting device 181X, for example, exhibits irregular luminance. Thereafter, the step S5 can be performed and a second micro light emitting device 182 can be disposed on the first backup electrical pad 172. The details of disposing the second micro light emitting device 182 is similar to the first micro light emitting device 181 described in step S3, and therefore are not repeated here to avoid duplicity.

Referring to FIG. 2 and FIGS. 7A and 7B, in an embodiment, the second micro light emitting device 182 is disposed according to the test result and the position information collected by the data acquisition module in step S4. More specifically, according to the test result and the position information of each of the first micro light emitting device 181, the position of each defective first micro light emitting device 181X can be obtained. As a result, a transfer device can dispose the second micro light emitting device 182 into each sub-pixel P having the defective first micro light emitting device 181X according to the position information of each defective first micro light emitting device 181X.

As shown in FIGS. 7A and 7B, after disposing the second micro light emitting device 182, the connection between the primary electrical pad 171 and the sub-pixel circuit 120 is disabled. More specifically, the control line 161 between the defective first micro light emitting device 181X and the sub-pixel control circuit 120 can be cut off. In one embodiment, the disabling process can be performed by a laser cutting process, but the present invention is not limited thereto.

In an embodiment, after disabling the connection between the primary electrode 171 and the sub-pixel circuit 120, the manufacturing method of the LED display device 10 proceeds back to the step S4 where the second micro light emitting device 182 is tested. Similarly, if the second micro light emitting device 182 is tested to be normal, the steps S7˜S9 are performed. That is, the passivation layer 180 is formed to cover the defective first micro light emitting device 181X and the second micro light emitting device 182. In the embodiment of FIG. 7B, the openings O1 and O2 are formed in the passivation layer 180 to expose a portion of the defective first micro light emitting device 181X and the second micro light emitting device 182. The opposite electrode 190 is formed to electrically connect the exposed portion of the defective first micro light emitting device 181X and the second micro light emitting device 182. The details of performing step S7˜S9 to the second micro light emitting diode 182 is similar to the first micro light emitting diode 181, and therefore are not repeated here to avoid duplicity.

Referring to FIG. 7C, in some embodiments, before forming the opposite electrode 190, an insulating layer 200 is formed in the opening O1. More specifically, the insulating layer 200 covers the exposed portion of the defective first micro light emitting device 181X, so as to insulate the opposite electrode 190 from the defective first micro light emitting device 181X. As a result, in the embodiment of FIG. 7C, the disabling step S6 may be optional. In various embodiments, the insulating layer 200 may be made of organic material or inorganic material, and the insulating layer 200 may be formed by, for example, an inkjet printing process.

FIG. 8A is a top view of the sub-pixel P illustrating manufacturing steps S5 and S6 after testing of defective second micro light emitting device 182X. FIG. 8B is a cross-sectional view of FIG. 8A taken along line 8. Similarly, if the detection test in step S4 indicates that the second micro light emitting device 182X is defective, the steps S5˜S6 are performed. That is, a third micro light emitting device 183 is disposed on the second backup electrical pad 173. The connection between the sub-pixel circuit 120 and the first backup electrical pad 172 is disabled. The details of performing the steps S5˜S6 to the third micro light emitting diode 183 is similar to the second micro light emitting diode 182, and therefore are not repeated here to avoid duplicity.

With reference made to FIG. 8B, after disabling the connection between the sub-pixel circuit 120 and the first backup electrical pad 172, the manufacturing method of the LED display device 10 proceeds back to the step S4 where the third micro light emitting device 183 is tested. Then, according to the test result of the third micro light emitting device 183, the manufacturing method of the LED display device 10 selectively proceeds to steps S5˜S6 or steps S7˜S9. Taking FIG. 8B as an example, the third micro light emitting device 183 is tested to be normal. Thereafter, the passivation layer 180 covers the third micro light emitting device 183 and also covers the defective first micro light emitting device 181X and the defective second micro light emitting device 182X. Openings O1 and O3 in the passivation layer 180 are formed to respectively expose a portion of the defective first micro light emitting device 181X, and the third micro light emitting device 183. An opposite electrode 190 is formed to connect the exposed portion of the third micro light emitting device 183. In some embodiments, an insulating layer 200 is formed in the openings O1, so as to insulate the opposite electrode 190 from the defective first micro light emitting devices 181X. In this case, the disabling step S6 may be optional because the defective first micro light emitting devices 181X is not electrically connected with the opposite electrode 190. However, in another embodiments, if the disabling step S6 is performed, the insulating layer 200 may be optional, and the opposite electrode 190 may be contacted with the exposed part of the defective first micro light emitting device 181X through the opening O1.

Referring back to FIG. 2, in practical application, some of the sub-pixels P may include only one normal light emitting device (for example, FIG. 6) and some of the sub-pixels P may include one normal light emitting diode and at least one defective light emitting device (for example, FIGS. 7B and 8B). As a result, after the passivation layer 180 covers all of the micro light emitting device within each sub-pixel P, a photo mask may be used to form the opening O1 in each sub-pixel P first. Thereafter, the opening O2 and the opening O3 are selectively formed if the first backup electrical pad 172 and/or the second backup electrical pad 173 has a light emitting device thereon. In some embodiments, the opening O2 and the opening O3 can be formed by using the laser beam to exposure the passive layer 180 made of positive photoresist materials. In other embodiments, after ensuring the third micro light emitting device 183 on the second backup electrical pad 173 is tested to be normal, the opening O3 can be formed individually.

FIG. 9 is an enlarged cross-sectional of the sub-pixel with multiple openings and opposite electrodes on the micro light emitting device in accordance with an embodiment of the present invention. As shown in FIG. 9, in the present embodiment, the micro light emitting device 900 is a vertical type micro LED, which including a first type semiconductor layer 901, an active layer 902 and a second type semiconductor layer 903, in which the active layer is disposed between the first type semiconductor layer 901 and the second type semiconductor layer 903. In the present embodiment, two openings O4, O5 may be formed in the passivation layer 980, and two opposite electrodes 991 and 992 cover the openings O4, O5 and are separated from each other. By such configuration, electrical potential of the opposite electrodes 991 and 992 can be individually controlled. As a result, the current flowing through the micro light emitting device 900 is controllable and variable, and the brightness of the micro light emitting device 900 can be adjusted accordingly.

All the features disclosed in this specification (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

Any element in a claim that does not explicitly state “means for” performing a specified function, or “step for” performing a specific function, is not to be interpreted as a “means” or “step” clause as specified in 35 U.S.C. §112, 6th paragraph. In particular, the use of “step of” in the claims is not intended to invoke the provisions of 35 U.S.C. §112, 6th paragraph.

1-18. (canceled)

19. An LED display device, comprising:
a substrate comprising at least one sub-pixel;
at least one sub-pixel circuit disposed on the substrate;
a plurality of electrical pads disposed inside the sub-pixel and electrically connected with the sub-pixel circuit; and
a micro light emitting device disposed on one of the electrical pads.

20. The LED display device of claim 19, further comprising:
a defective micro light emitting device disposed on another one of the electrical pads, wherein the sub-pixel circuit is unconnected with said another one of the electrical pads.

21. The LED display device of claim 20, further comprising:
a passivation layer covers the micro light emitting device and the defective micro light emitting device, wherein the passivation layer has at least one opening to expose a portion of the micro light emitting device; and
at least one opposite electrode electrically connected to the exposed portion of the micro light emitting device.

22. The LED display device of claim 21, wherein the at least one opening exposes a portion of the defective micro light emitting device, and the LED display device further comprises an insulating layer to cover the exposed portion of the defective micro light emitting device.

23. The LED display device of claim 20, wherein the micro light emitting device and the defective micro light emitting device are a micro LED.

24. The LED display device of claim 19, wherein the plurality of the electrical pads have substantially the same shape.

25. The LED display device of claim 19, wherein the plurality of the electrical pads have variety of shapes.
